(19) United States
(12) Patent Application Publication
(10) Pub. No.: US 2017/0245440 A1
(43) Pub. Date: Aug. 31, 2017

(54) ARRAY OF LED ILLUMINATION MODULES OPTIMIZED FOR INITIAL PLANT GROWTH STAGE AND ILLUMINATION DEVICE INCLUDING THE SAME FOR PLANT FACTORY

(71) Applicant: FUTUREGREEN AGRICULTURAL CO., LTD., Suwon-si, Gyeonggi-do (KR)

(72) Inventors: Sung-Bin CHO, Suwon-si, Gyeonggi-do (KR); Ji-Dong KIM, Suwon-si, Gyeonggi-do (KR); Ki-Biak KWON, Hwaseong-si, Gyeonggi-do (KR)

(73) Assignee: FUTUREGREEN AGRICULTURAL CO., LTD., Suwon-si, Gyeonggi-do (KR)

(21) Appl. No.: 15/519,642

(22) PCT Filed: Oct. 12, 2015
(86) PCT No.: PCT/KR2015/010724

§ 371 Date: Apr. 17, 2017

(30) Foreign Application Priority Data
Oct. 29, 2014 (KR) 10-2014-0148749

(51) Int. Cl. A01G 7/04; H01L 25/075; F21V 15/01; H01L 33/50; F21V 3/00; F21V 19/00

(52) U.S. Cl. CPC A01G 7/045; F21V 3/00; F21V 19/003; F21V 15/01; H01L 33/505; H01L 33/504; H01L 25/0753; F21Y 2113/13

(57) ABSTRACT

Disclosed is an illumination module array for a plant factory, the array comprising: first blue LED chips; second blue LED chips; a first combination of RGY phosphors applied on the first chip to form a first RGY phosphors-applied LED chip; a second combination of RGY phosphors applied on the second chip to form a second RGY phosphors-applied LED chip, wherein the first combination is configured by combining red, green, and yellow phosphors that light emission from the first RGY phosphors-applied LED chip has a spectrum having a relatively higher intensity in a red wavelength range; wherein the second combination is configured by combining red, green, and yellow phosphors that light emission from the second RGY phosphors-applied LED chip and has a spectrum having a relatively shaper change of an intensity thereof in a blue wavelength range.

BACKGROUND

Field of the Present Disclosure

The present disclosure relates to an array of LED illumination modules to adjust a spectral configuration of light emission therefrom for effective initial plant growth stage.

More particularly, the present disclosure an array of LED illumination modules to adjust a spectral configuration of light emission therefrom for effective initial plant growth stage wherein each of first LED illumination modules among the array has a first blue LED chip and a first combination of RGY phosphors (red, green, yellow phosphors) applied onto a light emission face of the first blue LED chip, and each of second LED illumination modules among the array has a second blue LED chip and a second combination of RGY phosphors (red, green, yellow phosphors) applied onto a light emission face of the second blue LED chip, and the first combination is different from the second combination.

Discussion of Related Art

Generally, plants cultivated indoor or in a plant factory receive light energy using artificial illumination similar to natural light instead of natural light to control plant growth.

Although there are many ways to realize such artificial lighting, it is very important to adjust light intensity based on wavelength in the artificial lighting depending on the growth cycle of plants. This is a core technology in plant factories.

Here, artificial light (for example, LED light module) is artificially made, unlike natural light (solar light). Therefore, the plant growth is very sensitive to the intensities based on wavelength regions of the LED lighting device. This is the case especially at the beginning of plant growth.

In consideration of this point, various lighting devices using LED have been developed. Among them, red LED chips have been widely adopted to realize a red wavelength band which is very important for plant growth.

The red wavelength region is very important throughout the entire growth period of the plant. However, only the red wavelength region may not contribute to the early growth period of the plant, which is an important period for determining mature plant outcome during the growth period of the plant. For example, a blue wavelength region may contribute to the early growth period of the plant.

In addition, the LED lighting module conventionally used in the plant factory adopts the red LED chip light source in order to secure the light quantity in the red wavelength region. However, these LED red chip light sources are disadvantageously expensive. Therefore, a technology for constructing an LED lighting module for a plant factory that may promote plant growth while adopting an blue LED chip light source having a relatively low production cost is desired.

### PRIOR ART DOCUMENT

Korean patent application No.10-2013-0070956 “LED illumination module for plant factory and LED illumination device including the same”

Korean patent application No.10-2009-0017700 “LED illumination device for enhancing plant growth”

Korean patent application No.10-2010-0028266 “LED illumination device for plant factory and method for manufacturing the same”

### SUMMARY

The present disclosure has been made in view of the above points. It is an object of the present disclosure to provide an array of LED illumination modules to emit light having an intensity with a red wavelength region suitable for an entire growth period of a plant, and, at the same time, an intensity with wavelength region important for early growth of a plant, thereby to optimize spectrum of the light emission from the array, not only suitable for the overall growth duration of the plant, but also for the initial growth stage thereof. Further, it is an object of the present disclosure to provide an LED lighting device equipped with the array of LED illumination modules.

In one aspect of the present disclosure, there is provided an array of LED illumination modules for a plant factory to emit light spectrum optimized for an initial growth stage of a plant, the array comprising: at least one first blue LED chip to emit blue light; at least one second blue LED chip to emit blue light; a first combination of RGY phosphors applied on a light emission face of the first blue LED chip to form a first RGY phosphors-applied blue LED chip; a second combination of RGY phosphors applied on a light emission face of the second blue LED chip to form a second RGY phosphors-applied blue LED chip, wherein the first combination of RGY phosphors is configured by combining red, green, and yellow phosphors that first light emission from the first RGY phosphors-applied blue LED chip has a spectrum having a relatively higher intensity in a wavelength range corresponding to a red color; wherein the second combination of RGY phosphors is configured by combining red, green, and yellow phosphors that second light emission from the second RGY phosphors-applied blue LED chip and has a spectrum having a relatively shaper change of an intensity thereof in a wavelength range corresponding to a blue color, wherein the first and second light emissions together form combined light emission, wherein the combined light emission has a first intensity peak in a range of 560 nm to 660 nm, and a second intensity peak in range of 430 nm to 460 nm, and a minimum intensity level in a range of 465 nm to 490 nm, wherein the minimum intensity level is higher than a maximum intensity in a range of wavelengths above 700 nm.

In one implementation of the array, the combined light emission has a third intensity peak in a range of 630 nm to 660 nm, wherein the third intensity peak is separated from the first peak.

In one implementation of the array, a number of the first RGY phosphors-applied blue LED chips is arranged along a length direction of the array, and a number of the second RGY phosphors-applied blue LED chips is arranged along the length direction of the array, wherein the number of the first RGY phosphors-applied blue LED chips is larger 1.5 to 3.5 times inclusive than the number of the second RGY phosphors-applied blue LED chips such that the second peak is higher than the first and third peaks.

In one implementation of the array, a number of the first RGY phosphors-applied blue LED chips is arranged along a length direction of the array, and a number of the second RGY phosphors-applied blue LED chips is arranged along the length direction of the array, wherein the number of the first RGY phosphors-applied blue LED chips is larger 4 to 6 times inclusive than the number of the second RGY phosphors-applied blue LED chips such that the second peak is lower than the first and third peaks.

In another aspect of the present disclosure, there is provided an illumination device for a plant factory to emit light spectrum optimized for an initial growth stage of a plant, the device comprising: the above-defined array; a circuit board on which the array is mounted, wherein the circuit board has patterned circuit wires to control turn on/off of the LED chips and power supply to the LED chips; and a frame configured to support the circuit board thereon and secure the circuit board thereto.

In one implementation of the device, the device further comprises a cover removably attached to the frame on a bottom edge thereof, wherein the cover is configured to protect the circuit board on the frame and the array mounted on the circuit board. In one implementation of the device, the first and second blue LED chips are linearly arranged on the circuit board and spaced from each other in an equidistance manner.

In accordance with the present disclosure, the array of LED illumination modules emits light having an intensity with a red wavelength region suitable for an entire growth period of a plant, and, at the same time, an intensity with wavelength region important for early growth of a plant, thereby to optimize spectrum of the light emission from the array, not only suitable for the overall growth duration of the plant, but also for the initial growth stage thereof.

Further, in accordance with the present disclosure, the arrangement of the first RGY phosphors-applied blue LED chips and the second RGY phosphors-applied blue LED chips may be adjusted to achieve the spectrum not only suitable for the overall growth duration of the plant, but also for the initial growth stage thereof. This approach may be cost-economical compared to the conventional approach.

### BRIEF DESCRIPTION OF THE DRAWINGS

FIG. 1 illustrates an illumination device for a plant factory in accordance with a first embodiment of the present disclosure.

FIG. 2 illustrates a side elevation view of the illumination device for a plant factory and an enlarged view of LED illumination modules thereof, in accordance with a first embodiment of the present disclosure.

FIG. 3 illustrates a graph showing an intensity over a wavelength for light emitted from the illumination device for a plant factory in accordance with a first embodiment of the present disclosure.

FIG. 4 illustrates an illumination device for a plant factory in accordance with a second embodiment of the present disclosure.

FIG. 5 illustrates a side elevation view of the illumination device for a plant factory and an enlarged view of LED illumination modules thereof, in accordance with a second embodiment of the present disclosure.

FIG. 6 illustrates a graph showing an intensity over a wavelength for light emitted from the illumination device for a plant factory in accordance with a second embodiment of the present disclosure.

FIG. 7 illustrates an illumination device for a plant factory in accordance with a third embodiment of the present disclosure.

FIG. 8 illustrates a side elevation view of the illumination device for a plant factory and an enlarged view of LED illumination modules thereof, in accordance with a third embodiment of the present disclosure.

FIG. 9 illustrates a graph showing an intensity over a wavelength for light emitted from the illumination device for a plant factory in accordance with a third embodiment of the present disclosure.

FIG. 10 illustrates an illumination device for a plant factory in accordance with a fourth embodiment of the present disclosure.

FIG. 11 illustrates an illumination device for a plant factory in accordance with a fifth embodiment of the present disclosure.

FIG. 12 illustrates an illumination device for a plant factory in accordance with a sixth embodiment of the present disclosure.

### DETAILED DESCRIPTIONS

Hereinafter, embodiments of the present disclosure will be described in details with reference to the drawings.

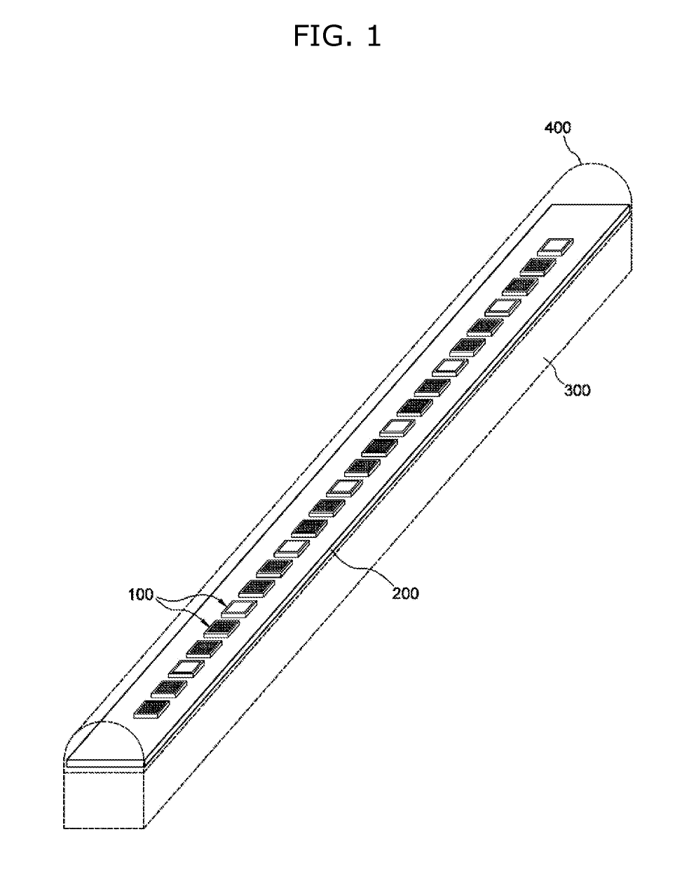

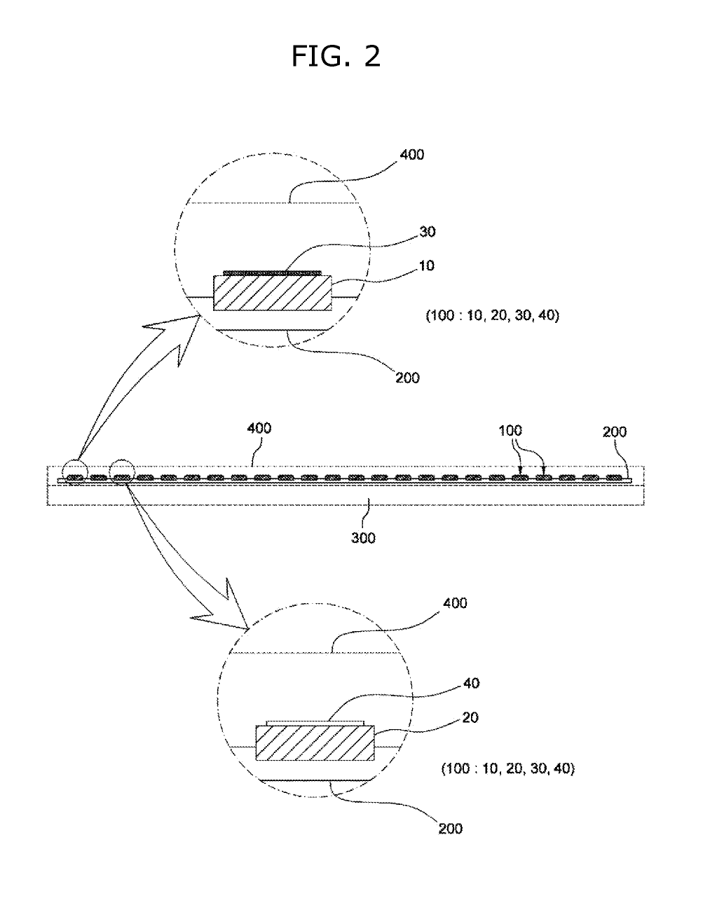

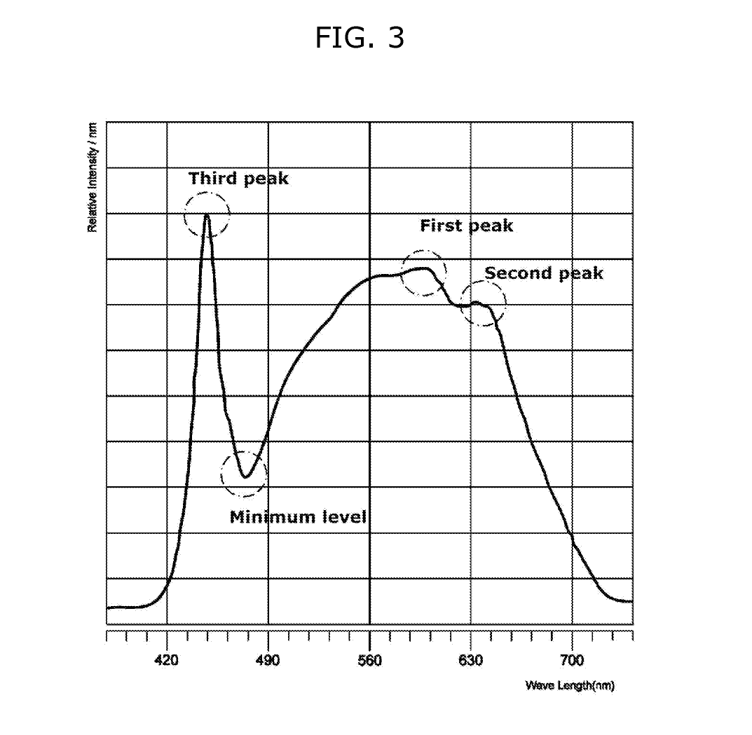

FIG. 1 illustrates an illumination device for a plant factory in accordance with a first embodiment of the present disclosure. FIG. 2 illustrates a side elevation view of the illumination device for a plant factory and an enlarged view of LED illumination modules thereof, in accordance with a first embodiment of the present disclosure. FIG. 3 illustrates a graph showing an intensity over a wavelength for light emitted from the illumination device for a plant factory in accordance with a first embodiment of the present disclosure.

Referring to FIG. 1 to FIG. 3, the illumination device for a plant factory in accordance with a first embodiment of the present disclosure may include an array of LED illumination modules 100. The array of the LED illumination module 100 may include a first blue LED chip 10, a second blue LED chip 20, a first combination of RGY phosphors 30, and a second combination of RGY phosphors 40.

When the first blue LED chip 10 receive a power from an external power supply, the chip 10 may emit blue light. The first combination of RGY phosphors 30 may be applied to a light emission surface of the first blue LED chip 10 to form a first RGY phosphors-applied blue LED chip. In order to form the first combination of RGY phosphors 30, red, green, and yellow phosphors may be combined such that light emission from the first RGY phosphors-applied blue LED chip 10 and 30 exhibit white light having a relatively higher intensity in a wavelength range corresponding to a red color.

When the second blue LED chip 20 receive a power from an external power supply, the chip 20 may emit blue light. The second combination of RGY phosphors 40 may be applied to a light emission surface of the second blue LED chip 20 to form a second RGY phosphors-applied blue LED chip. In order to form the second combination of RGY phosphors 40, red, green, and yellow phosphors may be combined such that light emission from the second RGY phosphors-applied blue LED chip 20 and 40 exhibit white light having a relatively larger change of an intensity thereof in a wavelength range corresponding to a blue color.

First light emission from the first RGY phosphors-applied blue LED chip 10 and 30 and second light emission from the second RGY phosphors-applied blue LED chip 20 and 40 may be combined to from combined light emission. The first RGY phosphors-applied blue LED chip 10 and 30 and second RGY phosphors-applied blue LED chip 20 and 40 may be mounted as respective LED illumination modules 100 on the single illumination device. Thus, the single illumination device may have the combined light emission as shown in FIG. 3. FIG. 3 illustrates a graph showing an intensity over a wavelength for the combined light emission from the illumination device for a plant factory in accordance with a first embodiment of the present disclosure.

The first combination of RGY phosphors 30 may be formed by combining red, green, and yellow phosphors such that the first combination of RGY phosphors 30 may affect a spectrum for the light emission from the first blue LED chip 10.

In one embodiment, the first combination of RGY phosphors 30 may be formed by combining red, green, and yellow phosphors such that light emission from the first RGY phosphors-applied blue LED chip 10 and 30 exhibit white light having a relatively higher intensity in a wavelength range corresponding to a red color. In this connection, as shown in FIG. 3, the first combination of RGY phosphors 30 may contribute to the relative higher intensity of the combined light emission in a range of wavelengths corresponding to a red color, that is, in a range of 560 nm to 660 nm.

The first light emission from the first RGY phosphors-applied blue LED chip 10 and 30 and second light emission from the second RGY phosphors-applied blue LED chip 20 and 40 may be combined to from the combined light emission with the spectrum as shown in FIG. 3. In this spectrum, the first combination of RGY phosphors 30 may contribute to a first peak in a range of 560 nm to 625 nm and a second peak in range of 630 nm to 660 nm.

Further, as shown in FIG. 3, in the range of 560 nm to 660 nm, the first peak is higher than the second peak. In this connection, the first combination of RGY phosphors 30 may be formed by combining the red, green, and yellow phosphors such that the first peak is higher than the second peak. This may be beneficial for entire plant growth duration.

At the same time, this first light emission may be combined with the second light emission from the second RGY phosphors-applied blue LED chip 20 and 40 which may be formed by applying the second combination of RGY phosphors 40 on the light emission surface of the second blue LED chip 20. Thus, the single illumination device for a plant factory in accordance with a first embodiment of the present disclosure may have the combined light emission of the first and second emissions, as shown in FIG. 3.

Further, as shown in FIG. 3, the first combination of RGY phosphors 30 may contribute to the first peak in a range of 560 nm to 625 nm and the second peak in range of 630 nm to 660 nm. Furthermore, as shown in FIG. 3, in the range of 560 nm to 660 nm, the first peak is higher than the second peak. This spectral configuration may be beneficial for the entire plant growth duration.

It should be noted that the resulting spectrum for the combined light emission may be primarily affected by the first combination of RGY phosphors 30 in in a range of 560 nm to 660 nm, and may be secondarily affected by the second combination of RGY phosphors 40 in a range of 430 nm to 490 nm as shown in FIG. 3.

The second combination of RGY phosphors 40 may be formed by combining red, green, and yellow phosphors such that the second combination of RGY phosphors 40 may affect a spectrum for the light emission from the second blue LED chip 20.

In one embodiment, the second combination of RGY phosphors 40 may be formed by combining red, green, and yellow phosphors such that light emission from the second RGY phosphors-applied blue LED chip 20 and 40 has a sharp intensity change in a wavelength range corresponding to a blue color. In this connection, as shown in FIG. 3, the second combination of RGY phosphors 40 may contribute to a higher intensity of the combined light emission in a range of 430 nm to 460 nm and a lower intensity of the combined light emission in a range of 465 nm to 490 nm.

The first light emission from the first RGY phosphors-applied blue LED chip 10 and 30 and second light emission from the second RGY phosphors-applied blue LED chip 20 and 40 may be combined to from the combined light emission with the spectrum as shown in FIG. 3. In this spectrum, the second combination of RGY phosphors 40 may contribute to a peak intensity of the combined light emission in a range of 430 nm to 460 nm and a valley intensity of the combined light emission in a range of 465 nm to 490 nm. Hereinafter, the peak intensity of the combined light emission in a range of 430 nm to 460 nm may be referred to as a third peak. The valley intensity of the combined light emission in a range of 465 nm to 490 nm may be referred to as a minimum level.

Further, the second combination of RGY phosphors 40 may be formed by combining red, green, and yellow phosphors such that the valley intensity of the combined light emission in a range of 465 nm to 490 nm is higher than all intensities in a range of wavelengths above 700 nm, as shown in FIG. 3. This may be beneficial for an initial plant growth duration.

At the same time, this second light emission may be combined with the first light emission from the first RGY phosphors-applied blue LED chip 10 and 30 which may be formed by applying the first combination of RGY phosphors 30 on the light emission surface of the first blue LED chip 10. Thus, the single illumination device for a plant factory in accordance with a first embodiment of the present disclosure may have the combined light emission of the first and second emissions, as shown in FIG. 3.

In this way, the first combination of RGY phosphors 30 may contribute to the light intensity in a wavelength range corresponding to a red color, while the second combination of RGY phosphors 40 may contribute to the light intensity in a wavelength range corresponding to a blue color. Thus, this spectral configuration for the combined emission as shown in FIG. 3 may be beneficial for an initial plant growth duration.

In one embodiment, as shown in FIG. 1 and FIG. 2, a number of the first RGY phosphors-applied blue LED chips 10 and 30 may be arranged along the length direction of the present illumination device. Further, a number of the second RGY phosphors-applied blue LED chips 20 and 40 may be arranged along the length direction of the present illumination device. In this connection, the number of the first RGY phosphors-applied blue LED chips 10 and 30 may be larger 1.5 to 3.5 times inclusive than the number of the second RGY phosphors-applied blue LED chips 20 and 40. This may lead to the configuration that the third peak is higher than the first peak. This may result in the spectrum as shown in FIG. 3, which may be beneficial for an initial plant growth duration.

That is, due to the configuration that the third peak is higher than the first peak, for the initial plant growth duration, optimal photosynthesis may be achieved for the division or growth of each organ of the plant. Otherwise, only the red light may not suffice.

As shown in FIG. 1 and FIG. 2, the illumination device for a plant factory in accordance with a first embodiment of the present disclosure may include an array of the above defined LED illumination modules 100 in accordance with a first embodiment of the present disclosure, a circuit board 200, a frame 300, and a cover 400.

In this connection, the circuit board 200 may have the array of the LED illumination modules 100 mounted thereon. The circuit board 200 may have patterned circuit wires to control turn on/off of the LED illumination module 100 and power supply to the LED illumination modules 100.

The frame 300 may be configured to support the circuit board 200 thereon and secure the circuit board 200 thereto. Further, the frame 300 may be fixed to a support frame (not shown) in the plant factory.

The cover 400 may be removably attached to the frame 300 at a bottom edge thereof. The cover 400 may protect the circuit board 200 on the frame 300 and the array of the LED illumination modules 100 mounted on the circuit board 200. In this connection, the first and second blue LED chips 10 and 20 may be linearly arranged on the circuit board 200 and spaced from each other in an equidistance manner, as shown in FIG. 1 and FIG. 2. In one embodiment, two first blue LED chips 10 and one second blue LED chip 20 may be repeatedly alternated and may be configured as a repeating unit.

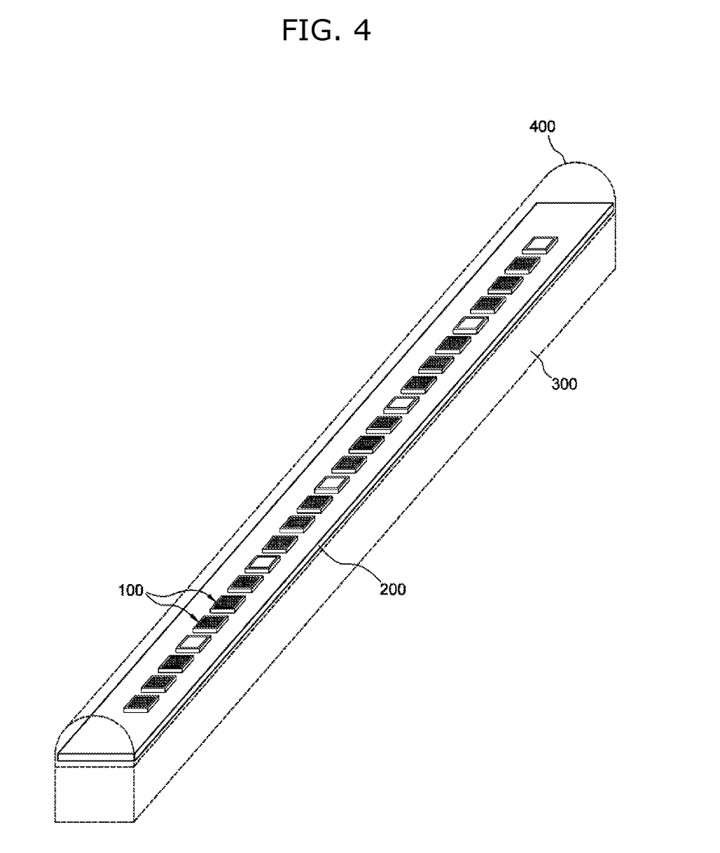

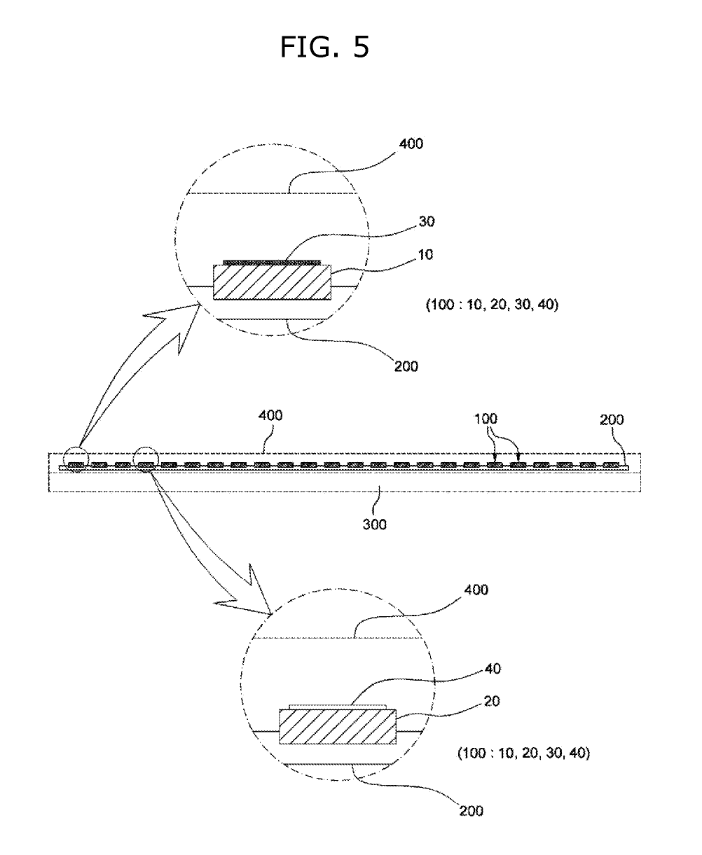

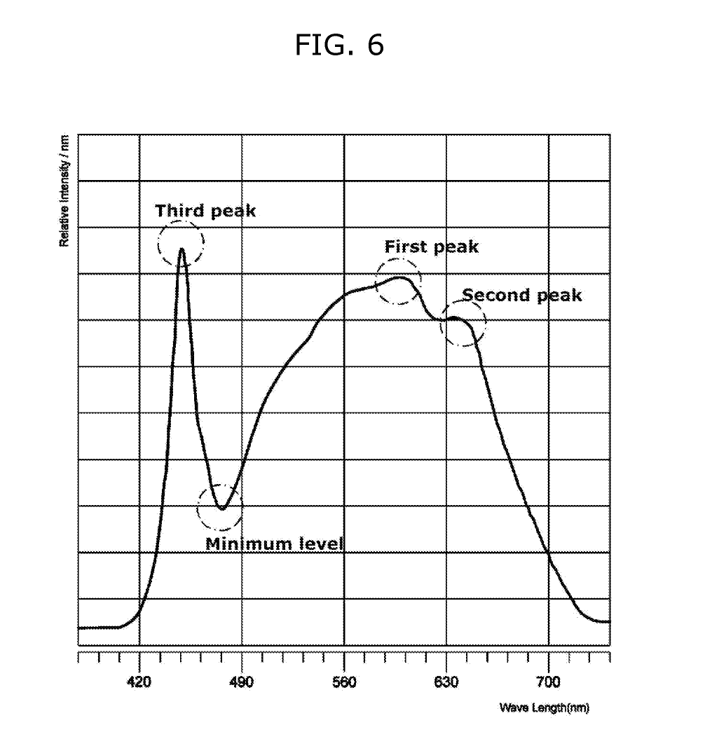

FIG. 4 illustrates an illumination device for a plant factory in accordance with a second embodiment of the present disclosure. FIG. 5 illustrates a side elevation view of the illumination device for a plant factory and an enlarged view of LED illumination modules thereof, in accordance with a second embodiment of the present disclosure. FIG. 6 illustrates a graph showing an intensity over a wavelength for light emitted from the illumination device for a plant factory in accordance with a second embodiment of the present disclosure.

Referring to FIG. 4 to FIG. 6, the illumination device for a plant factory in accordance with a second embodiment of the present disclosure may include an array of LED illumination modules 100. The array of the LED illumination module 100 may include a first blue LED chip 10, a second blue LED chip 20, a first combination of RGY phosphors 30, and a second combination of RGY phosphors 40.

The second embodiment may be same as the first embodiment in terms of each of configurations of the first blue LED chip 10, the second blue LED chip 20, the first combination of RGY phosphors 30, and the second combination of RGY phosphors 40.

However, the second embodiment may be different from the first embodiment in terms of arrangement of the first blue LED chips 10 and the second blue LED chips 20. In the second embodiment, the first blue LED chips 10 and the second blue LED chips 20 may be linearly arranged on the circuit board 200 and spaced from each other in an equidistance manner, as shown in FIG. 4 and FIG. 5. In this connection, three first blue LED chips 10 and one second blue LED chip 20 may be repeatedly alternated and be configured as a repeating unit. This arrangement may lead to an emission spectrum as shown in FIG. 6. The emission spectrum resulting from the second embodiment may effectively contribute to the initial plant stage as in the first embodiment.

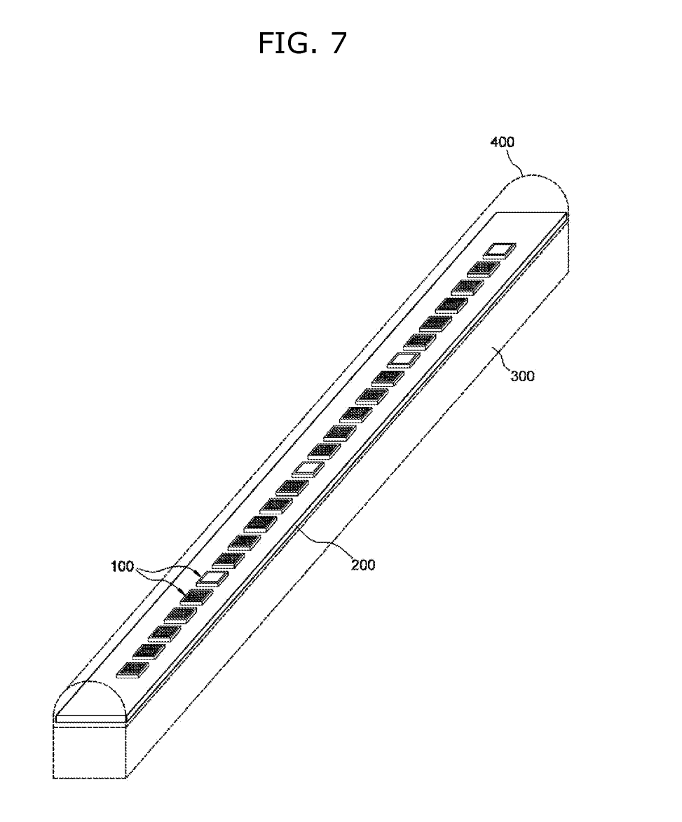

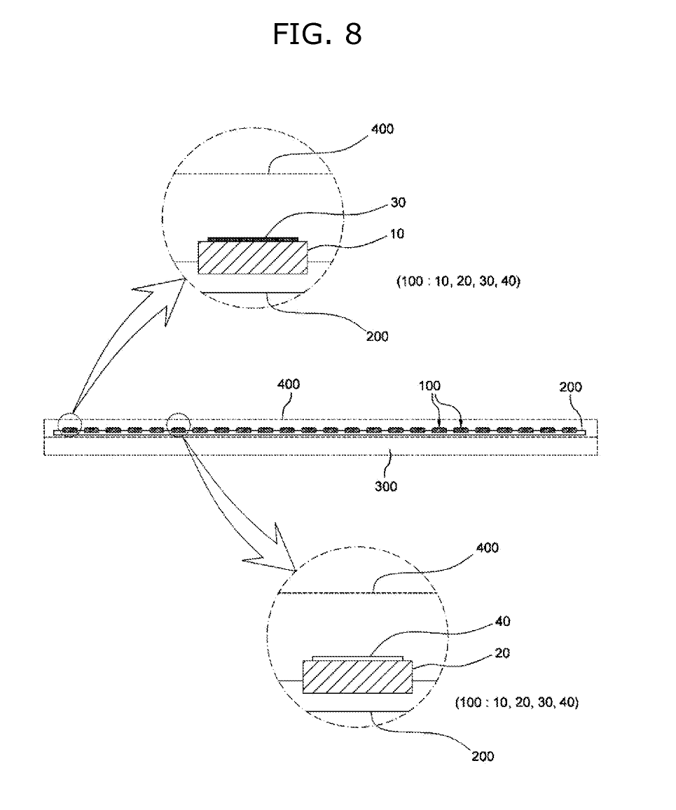

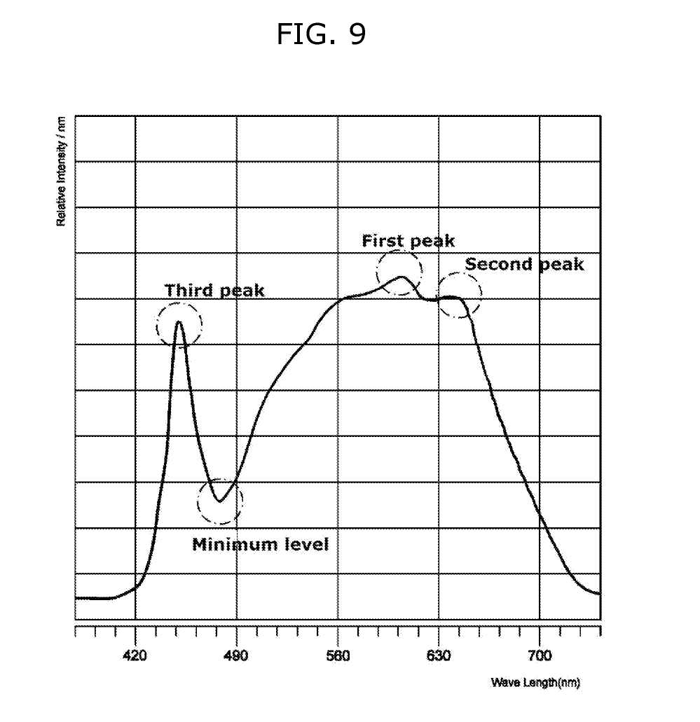

FIG. 7 illustrates an illumination device for a plant factory in accordance with a third embodiment of the present disclosure. FIG. 8 illustrates a side elevation view of the illumination device for a plant factory and an enlarged view of LED illumination modules thereof, in accordance with a third embodiment of the present disclosure. FIG. 9 illustrates a graph showing an intensity over a wavelength for light emitted from the illumination device for a plant factory in accordance with a third embodiment of the present disclosure.

Referring to FIG. 7 to FIG. 9, the illumination device for a plant factory in accordance with a third embodiment of the present disclosure may include an array of LED illumination modules 100. The array of the LED illumination module 100 may include a first blue LED chip 10, a second blue LED chip 20, a first combination of RGY phosphors 30, and a second combination of RGY phosphors 40.

The third embodiment may be same as the first embodiment in terms of each of configurations of the first blue LED chip 10, the second blue LED chip 20, the first combination of RGY phosphors 30, and the second combination of RGY phosphors 40.

However, the third embodiment may be different from the first embodiment in terms of numbers of the first blue LED chips 10 and the second blue LED chips 20 arranged on the circuit board 200. In the third embodiment, the first blue LED chips 10 and the second blue LED chips 20 may be linearly arranged on the circuit board 200 and spaced from each other in an equidistance manner, as shown in FIG. 7 and FIG. 8. In this connection, the number of arranged first blue LED chips 10 may be larger 4 to 6 times inclusive than the number of arranged second blue LED chips 20. This arrangement may lead to an emission spectrum as shown in FIG. 9. The emission spectrum resulting from the third embodiment may be different from the emission spectrum resulting from the first embodiment in that the second peak is higher than the third peak. The emission spectrum resulting from the third embodiment may effectively contribute to the initial plant stage.

In this connection, the emission spectrum resulting from the third embodiment may be suitable for some kind of plants, while the emission spectrums resulting from the first and second embodiments may be suitable for other kind of plants. Thus, depending on the kind of the target plant, the emission spectrum may be selected between the first, second and third embodiments.

In one example of the third embodiment, the first blue LED chips 10 and the second blue LED chips 20 may be linearly arranged on the circuit board 200 and spaced from each other in an equidistance manner, as shown in FIG. 7 and FIG. 9. In this connection, five first blue LED chips 10 and one second blue LED chip 20 may be repeatedly alternated and be configured as a repeating unit. This arrangement may lead to an emission spectrum as shown in FIG. 9. The emission spectrum resulting from the third embodiment may effectively contribute to the initial plant stage as in the first and second embodiments.

In this way, in the present disclosure, as described above with reference to the first, second and third embodiments, the arrangement of the first blue LED chips 10 with the first combination of RGY phosphors 30 applied thereto may overcome deficiency in terms of the plant growth related to a conventional array of red, blue and white LEDs

Although the arrangement of the first blue LED chips 10 with the first combination of RGY phosphors 30 applied thereto may result in the spectral configuration with the first peak and second peak as shown in FIG. 3, FIG. 6, FIG. 9 in a red wavelength region, only the arrangement of the first blue LED chips 10 with the first combination of RGY phosphors 30 applied thereto may not produce the spectral configuration with the third peak and the valley as shown in FIG. 3, FIG. 6, FIG. 9 in a blue wavelength region.

Therefore, the first blue LED chips 10 with the first combination of RGY phosphors 30 applied thereto may be alternately arranged with the second blue LED chips 20 with the second combination of RGY phosphors 40 applied thereto, as shown in FIG. 1, FIG. 4, and FIG. 7. In this way, the emission spectrum as shown in FIG. 3, FIG. 6, and FIG. 9 may be achieved which may be beneficial for the initial growth stage of the plant.

The arrangement of the second blue LED chips 20 with the second combination of RGY phosphors 40 applied thereto may result in the emission spectrum with an intensity in the range of 420 nm to 490 nm. However, the arrangement of the second blue LED chips 20 with the second combination of RGY phosphors 40 applied thereto may not contribute to an intensity in the range of 500 nm to 660 nm. Thus, the first blue LED chips 10 with the first combination of RGY phosphors 30 applied thereto may be alternately arranged with the second blue LED chips 20 with the second combination of RGY phosphors 40 applied thereto.

In one embodiment, a relatively larger amount of the first combination of RGY phosphors 30 may be applied onto the first blue LED chip 10 such that the first RGY phosphors-applied blue LED chip 10 and 30 has the emission spectrum with a relatively higher intensity in the range of 500 nm to 660 nm. This is because the first blue LED chip 10 itself has the blue emission. At the same time, a relatively smaller amount of the second combination of RGY phosphors 40 may be applied onto the second blue LED chip 20 since the second blue LED chip 20 itself has the emission spectrum with a relatively higher intensity in the range of 420 nm to 490 nm.

Different emission spectrums from those as shown in FIG. 3, FIG. 6, and FIG. 9 may be realized. To this end, an amount of the first combination of RGY phosphors 30 applied onto the first blue LED chip 10, an amount of the second combination of RGY phosphors 40 applied onto the second blue LED chip 20, and an amount ratio between red, green, and yellow phosphors in the first combination of RGY phosphors 30, and an amount ratio between red, green, and yellow phosphors in the second combination of RGY phosphors 40 may be adjusted. However, this approach may be costly.

In one embodiment, the arrangement of the first RGY phosphors-applied blue LED chips 10 and 30 and the second RGY phosphors-applied blue LED chips 20 and 40 may be adjusted to achieve the spectrums as shown in FIG. 3, FIG. 6, and FIG. 9. Further, the arrangement of the first RGY phosphors-applied blue LED chips 10 and 30 and the second RGY phosphors-applied blue LED chips 20 and 40 may be adjusted to vary the intensity in a range of 420 nm to 490 nm useful for the initial growth stage of the plant. This approach may be cost-economical.

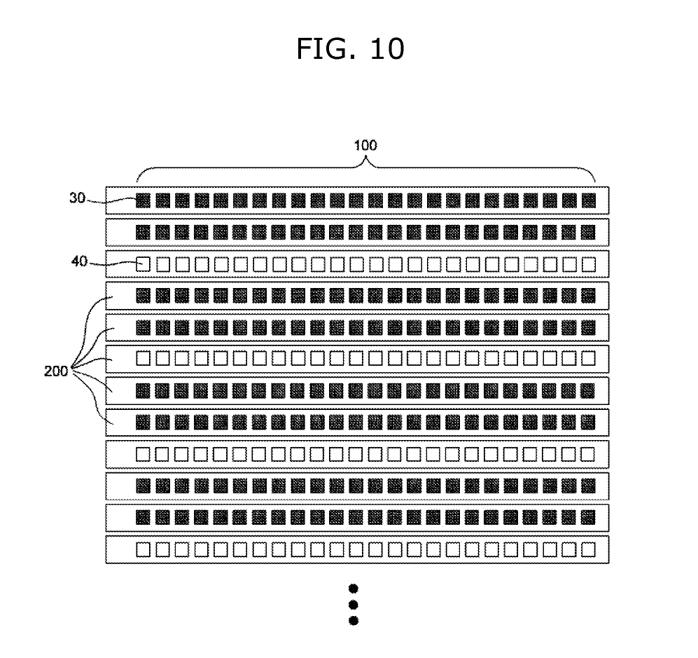

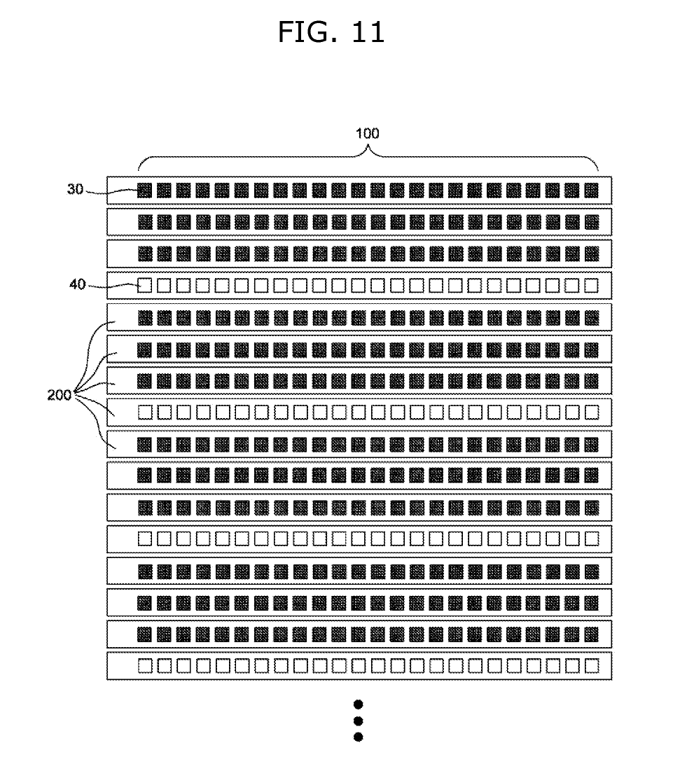

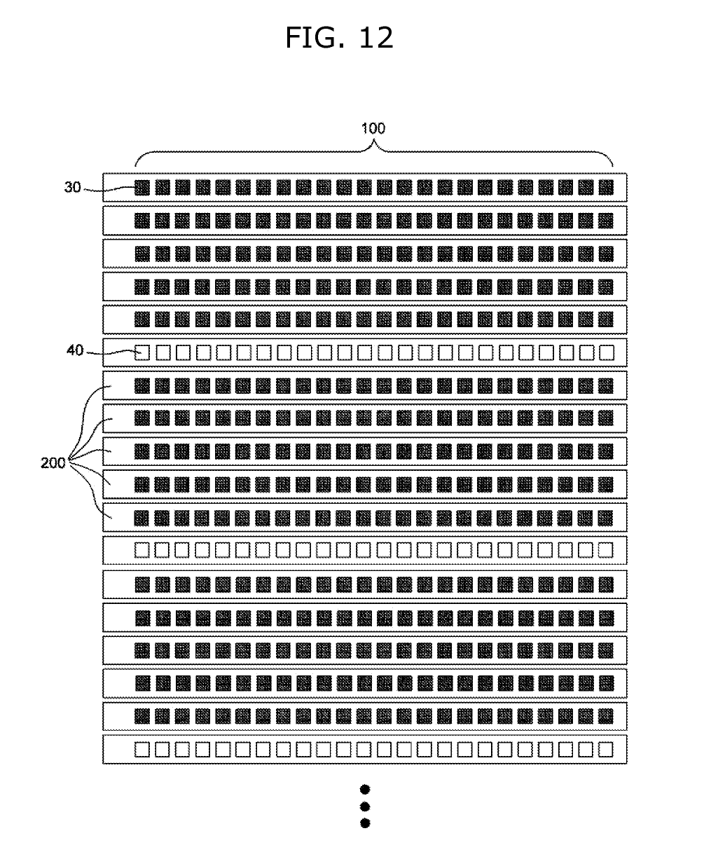

FIG. 10 illustrates an illumination device for a plant factory in accordance with a fourth embodiment of the present disclosure. FIG. 11 illustrates an illumination device for a plant factory in accordance with a fifth embodiment of the present disclosure. FIG. 12 illustrates an illumination device for a plant factory in accordance with a sixth embodiment of the present disclosure.

Referring to FIG. 1, FIG. 4, and FIG. 7, the first RGY phosphors-applied blue LED chips 10 and 30 and the second RGY phosphors-applied blue LED chips 20 and 40 may be alternately arranged linearly in a single line. However, the present disclosure may not be limited thereto. Referring to FIG. 10 to FIG. 12, rows of the first RGY phosphors-applied blue LED chips 10 and 30 and rows of the second RGY phosphors-applied blue LED chips 20 and 40 may be alternately arranged in a column direction so as to achieve the spectrums as shown in FIG. 3, FIG. 6, and FIG. 9.

In order to realize the spectrums as shown in FIG. 3, FIG. 6, and FIG. 9, rows of the first RGY phosphors-applied blue LED chips 10 and 30 and rows of the second RGY phosphors-applied blue LED chips 20 and 40 may be alternately arranged in a column direction on the circuit board 200 as follows:

In one embodiment, as shown in FIG. 10, two neighboring rows of the first RGY phosphors-applied blue LED chips 10 and 30 may be repeatedly and alternately arranged with a single row of the second RGY phosphors-applied blue LED chips 20 and 40 in a column direction on the circuit board 200 so as to realize the spectrum as shown in FIG. 3.

In one embodiment, as shown in FIG. 11, three neighboring rows of the first RGY phosphors-applied blue LED chips 10 and 30 may be repeatedly and alternately arranged with a single row of the second RGY phosphors-applied blue LED chips 20 and 40 in a column direction on the circuit board 200 so as to realize the spectrum as shown in FIG. 6.

In one embodiment, as shown in FIG. 12, five neighboring rows of the first RGY phosphors-applied blue LED chips 10 and 30 may be repeatedly and alternately arranged with a single row of the second RGY phosphors-applied blue LED chips 20 and 40 in a column direction on the circuit board 200 so as to realize the spectrum as shown in FIG. 9.

1. An array of LED illumination modules for a plant factory to emit light spectrum optimized for an initial growth stage of a plant, the array comprising:
at least one first blue LED chip 10 to emit blue light;
at least one second blue LED chip 20 to emit blue light;
a first combination of RGY phosphors 30 applied on a light emission face of the first blue LED chip to form a first RGY phosphors-applied blue LED chip 10 and 30;
a second combination of RGY phosphors 40 applied on a light emission face of the second blue LED chip to form a second RGY phosphors-applied blue LED chip 20 and 40,
wherein the first combination of RGY phosphors 30 is configured by combining red, green, and yellow phosphors that first light emission from the first RGY phosphors-applied blue LED chip 10 and 30 has a spectrum having a relatively higher intensity in a wavelength range corresponding to a red color;
wherein the second combination of RGY phosphors 40 is configured by combining red, green, and yellow phosphors that second light emission from the second RGY phosphors-applied blue LED chip 20 and 40 has a spectrum having a relatively shaper change of an intensity thereof in a wavelength range corresponding to a blue color,
wherein the first and second light emissions together form combined light emission, wherein the combined light emission has a first intensity peak in a range of 560 nm to 660 nm, and a second intensity peak in range of 430 nm to 460 nm, and a minimum intensity level in a range of 465 nm to 490 nm, wherein the minimum intensity level is higher than a maximum intensity in a range of wavelengths above 700 nm.

2. The array of claim 1, wherein the combined light emission has a third intensity peak in a range of 630 nm to 660 nm, wherein the third intensity peak is separated from the first peak.

3. The array of claim 2, wherein a number of the first RGY phosphors-applied blue LED chips 10 and 30 is arranged along a length direction of the array, and a number of the second RGY phosphors-applied blue LED chips 20 and 40 is arranged along the length direction of the array, wherein the number of the first RGY phosphors-applied blue LED chips 10 and 30 is larger 1.5 to 3.5 times inclusive than the number of the second RGY phosphors-applied blue LED chips 20 and 40 such that the second peak is higher than the first and third peaks.

4. The array of claim 2, wherein a number of the first RGY phosphors-applied blue LED chips 10 and 30 is arranged along a length direction of the array, and a number of the second RGY phosphors-applied blue LED chips 20 and 40 is arranged along the length direction of the array, wherein the number of the first RGY phosphors-applied blue LED chips 10 and 30 is larger 4 to 6 times inclusive than the number of the second RGY phosphors-applied blue LED chips 20 and 40 such that the second peak is lower than the first and third peaks.

5. An illumination device for a plant factory to emit light spectrum optimized for an initial growth stage of a plant, the device comprising:
the array 100 of claim 1;
a circuit board 200 on which the array is mounted, wherein the circuit board has patterned circuit wires to control turn on/off of the LED chips and power supply to the LED chips; and
a frame 300 configured to support the circuit board thereon and secure the circuit board thereto.

6. The device of claim 5, further comprising a cover 400 removably attached to the frame on a bottom edge thereof, wherein the cover is configured to protect the circuit board on the frame and the array mounted on the circuit board.

7. The device of claim 6, wherein the first and second blue LED chips are linearly arranged on the circuit board and spaced from each other in an equidistance manner.

8. An illumination device for a plant factory to emit light spectrum optimized for an initial growth stage of a plant, the device comprising:
the array 100 of claim 2;
a circuit board 200 on which the array is mounted, wherein the circuit board has patterned circuit wires to control turn on/off of the LED chips and power supply to the LED chips; and
a frame 300 configured to support the circuit board thereon and secure the circuit board thereto.

9. An illumination device for a plant factory to emit light spectrum optimized for an initial growth stage of a plant, the device comprising:
the array 100 of claim 3;
a circuit board 200 on which the array is mounted, wherein the circuit board has patterned circuit wires to control turn on/off of the LED chips and power supply to the LED chips; and
a frame 300 configured to support the circuit board thereon and secure the circuit board thereto.

10. An illumination device for a plant factory to emit light spectrum optimized for an initial growth stage of a plant, the device comprising:
the array 100 of claim 4;
a circuit board 200 on which the array is mounted, wherein the circuit board has patterned circuit wires to control turn on/off of the LED chips and power supply to the LED chips; and
a frame 300 configured to support the circuit board thereon and secure the circuit board thereto.
